(19) United States
(12) Patent Application Publication
(10) Pub. No.: US 2024/0413807 A1
(43) Pub. Date: Dec. 12, 2024

(54) ACOUSTIC WAVE DEVICE, HIGH FREQUENCY FILTER, AND FILTER CIRCUIT

(71) Applicant: Murata Manufacturing Co., Ltd., Nagaokakyo-shi (JP)

(72) Inventor: Yasuharu NAKAI, Nagaokakyo-shi (JP)

(21) Appl. No.: 18/630,218

(22) Filed: Apr. 9, 2024

(30) Foreign Application Priority Data
Jun. 8, 2023 (JP) 2023-094816

(51) Int. Cl. H03H 9/145; H03H 9/02; H03H 9/25; H03H 9/64

(52) U.S. Cl. CPC H03H 9/145; H03H 9/02559; H03H 9/02637; H03H 9/02866; H03H 9/02992; H03H 9/25; H03H 9/6483

(57) ABSTRACT

An acoustic wave device includes a substrate, an IDT electrode on the substrate, and a dielectric film on the substrate. The substrate includes a piezoelectric layer, a low acoustic velocity layer, and a high acoustic velocity layer in this order. The IDT electrode includes electrode fingers and busbar electrodes that connect the electrode fingers. On the piezoelectric layer, the dielectric film is located only in a region where the electrode fingers and the busbar electrodes are not located, between the busbar electrodes in a plan view of the substrate. A film thickness of the dielectric film is smaller than a film thickness of the electrode fingers.

### CROSS REFERENCE TO RELATED APPLICATIONS

This application claims the benefit of priority to Japanese Patent Application No. 2023-094816 filed on Jun. 8, 2023. The entire contents of this application are hereby incorporated herein by reference.

### BACKGROUND OF THE INVENTION

### 1. Field of the Invention

The present invention relates to acoustic wave devices, high frequency filters, and filter circuits.

### 2. Description of the Related Art

International Publication No. 2012/086639 discloses a surface acoustic wave filter (acoustic wave device) having a high Q value by using a substrate formed of a multilayer body including a high acoustic velocity support substrate, a low acoustic velocity layer, and a piezoelectric layer. According to the above-described configuration, a low loss of the surface acoustic wave filter can be realized.

### SUMMARY OF THE INVENTION

However, in a case of the acoustic wave device disclosed in International Publication No. 2012/086639, for example, unwanted waves can be reduced or prevented, and deterioration in a Q value can be reduced or prevented by optimizing Euler angles of the piezoelectric layer. However, a fractional band width is limited to a specific range by the optimized Euler angles, and the fractional band width is less likely to be adjusted. In addition, when capacitance of the acoustic wave device having a thin piezoelectric layer needs to be ensured, the acoustic wave device has to increase in size due to the substrate formed of the multilayer body.

Therefore, example embodiments of the present invention is made to solve the above-described issue, and aims to provide small acoustic wave devices, high frequency filters, and filter circuits which can each adjust a fractional band width without causing deterioration in a Q value.

According to an aspect of an example embodiment of the present invention, an acoustic wave device includes a substrate, an interdigital transducer (IDT) electrode on the substrate, and a first dielectric film on the substrate, in which the substrate includes a piezoelectric layer on which the IDT electrode is located, a high acoustic velocity layer having a higher acoustic velocity of a bulk wave propagating through the piezoelectric layer than an acoustic velocity of the acoustic wave propagating through the piezoelectric layer, and a low acoustic velocity layer between the piezoelectric layer and the high acoustic velocity layer, and having a lower acoustic velocity of the bulk wave than the bulk wave propagating through the piezoelectric layer, the IDT electrode includes a plurality of first electrode fingers and a plurality of second electrode fingers parallel or substantially parallel to each other, a first busbar electrode to connect one ends of the plurality of first electrode fingers to each other, and a second busbar electrode to connect one ends of the plurality of second electrode fingers to each other, and facing the first busbar electrode with the plurality of first electrode fingers and the plurality of second electrode fingers interposed therebetween, on the piezoelectric layer, the first dielectric film is located only in a region where the plurality of first electrode fingers, the plurality of second electrode fingers, the first busbar electrode, and the second busbar electrode are not located, in a region between the first busbar electrode and the second busbar electrode in a plan view of the substrate, and a film thickness of the first dielectric film is smaller than a film thickness of the plurality of first electrode fingers and the plurality of second electrode fingers.

In addition, according to another aspect of an example embodiment of the present invention, an acoustic wave device includes a substrate, an interdigital transducer (IDT) electrode on the substrate, and a first dielectric film on the substrate, in which the substrate includes a piezoelectric layer on which the IDT electrode is located, a high acoustic velocity layer having a higher acoustic velocity of a bulk wave propagating through the piezoelectric layer than an acoustic velocity of the acoustic wave propagating through the piezoelectric layer, and a low acoustic velocity layer between the piezoelectric layer and the high acoustic velocity layer and having a lower acoustic velocity of the bulk wave than the bulk wave propagating through the piezoelectric layer, the IDT electrode includes a plurality of first electrode fingers and a plurality of second electrode fingers which are parallel or substantially parallel to each other, a first busbar electrode to connect one ends of the plurality of first electrode fingers to each other, and a second busbar electrode to connect one ends of the plurality of second electrode fingers to each other, and facing the first busbar electrode with the plurality of first electrode fingers and the plurality of second electrode fingers interposed therebetween, on the piezoelectric layer, the first dielectric film is located only in a region where the plurality of first electrode fingers and the plurality of second electrode fingers are not located in a plan view of the substrate, in a region where the plurality of first electrode fingers and the plurality of second electrode fingers overlap each other when viewed in a direction parallel or substantially parallel to the piezoelectric layer and perpendicular or substantially perpendicular to an extending direction of the plurality of first electrode fingers and the plurality of second electrode fingers, and a film thickness of the first dielectric film is smaller than a film thickness of the plurality of first electrode fingers and the plurality of second electrode fingers.

In addition, according to still another aspect of an example embodiment of the present invention, a high frequency filter includes an acoustic wave device according to another example embodiment of the present invention.

In addition, according to still another aspect of an example embodiment of the present invention, a filter circuit includes a plurality of the high frequency filters according to another example embodiment of the present invention that share one of the substrates, and the first dielectric film of a first high frequency filter in the plurality of high frequency filters and the first dielectric film of a second high frequency filter in the plurality of high frequency filters have different film thicknesses, materials, or compositions.

According to example embodiments of the present invention, it is possible to provide small acoustic wave devices, high frequency filters, and filter circuits which each can adjust a fractional band width without causing deterioration in a Q value.

The above and other elements, features, steps, characteristics and advantages of the present invention will become more apparent from the following detailed description of the example embodiments with reference to the attached drawings.

### BRIEF DESCRIPTION OF THE DRAWINGS

FIGS. 1A and 1B are a plan view and a sectional view of an acoustic wave device according to Example 1.

FIGS. 2A and 2B are a plan view and a sectional view of an acoustic wave device according to a comparative example.

FIG. 3A is a graph showing a relationship between a film thickness of a dielectric film and a change rate of a fractional band width of the acoustic wave devices according to Example 1 and the comparative example.

FIG. 3B is a graph showing a relationship between the film thickness of the dielectric film and a change rate of Qmax of the acoustic wave devices according to Example 1 and the comparative example.

FIG. 3C is a graph showing a relationship between a change rate of Qmax and a change rate of the fractional band width of the acoustic wave devices according to Example 1 and the comparative example.

FIG. 4A is a graph showing a relationship between a film thickness of a first dielectric film and a change rate of the fractional band width when a relative dielectric constant of the first dielectric film is changed in the acoustic wave device according to Example 1.

FIG. 4B is a graph showing a relationship between the film thickness of the first dielectric film and a change rate of Qmax when the relative dielectric constant of the first dielectric film is about 3.75 in the acoustic wave device according to Example 1.

FIG. 4C is a graph showing a relationship between the relative dielectric constant and a decreasing rate of the fractional band width when the change rate of the Qmax is about 80% in the acoustic wave device according to Example 1.

FIG. 5A is a graph showing a relationship between the film thickness of a first dielectric film and a change rate of the fractional band width when the first dielectric film is silicon nitride or silicon oxide.

FIG. 5B is a graph showing a relationship between the film thickness of the first dielectric film and a change rate of the fractional band width when the first dielectric film is yttrium oxide or silicon oxide.

FIG. 5C is a graph showing a relationship between the film thickness of the first dielectric film and a change rate of the fractional band width when the first dielectric film is aluminum oxide or silicon oxide.

FIG. 5D is a graph showing a relationship between the film thickness of the first dielectric film and a change rate of the fractional band width when the first dielectric film is tantalum oxide or silicon oxide.

FIG. 5E is a graph showing a relationship between the film thickness of the first dielectric film and a change rate of the fractional band width when the first dielectric film is titanium oxide or silicon oxide.

FIG. 5F is a graph showing a relationship between the film thickness of the first dielectric film and a change rate of the fractional band width when the first dielectric film is hafnium oxide or silicon oxide.

FIG. 5G is a graph showing a relationship between the film thickness of the first dielectric film and a change rate of the fractional band width when the first dielectric film is zirconium oxide or silicon oxide.

FIG. 5H is a graph showing a relationship between the film thickness of the first dielectric film and a change rate of the fractional band width when the first dielectric film is sialon or silicon oxide.

FIG. 6 is a graph showing a relationship between the film thickness of the first dielectric film and a change rate of the fractional band width when the piezoelectric layer of the acoustic wave device according to Example 1 is lithium niobate.

FIG. 7A is a plan view of an acoustic wave device according to Modification Example 1.

FIG. 7B is a plan view of an acoustic wave device according to Modification Example 2.

FIGS. 8A and 8B are a plan view and a sectional view of an acoustic wave device according to Example 2.

FIG. 9A is a view schematically showing an electrode configuration of an acoustic wave resonator according to an example embodiment and a view schematically showing the acoustic wave resonator.

FIG. 9B is a view schematically showing an electrode configuration of a longitudinally coupled resonator according to an example embodiment of the present invention and a view schematically showing the longitudinally coupled resonator.

FIG. 10A is a circuit configuration diagram of a ladder-type high frequency filter according to an example embodiment of the present invention.

FIG. 10B is a circuit configuration diagram of a high frequency filter including a longitudinally coupled resonator according to an example embodiment of the present invention.

FIG. 10C is a circuit configuration diagram of a high frequency filter including a plurality of the longitudinally coupled resonators according to an example embodiment of the present invention.

### DETAILED DESCRIPTION OF THE EXAMPLE EMBODIMENTS

Hereinafter, example embodiments of the present disclosure will be described in detail with reference to the drawings. All of the example embodiments described below represent comprehensive or specific examples. Numerical values, shapes, materials, configuration elements, or dispositions and connection structures of the configuration elements which are described in the following example embodiments are merely examples, and are not intended to limit the present invention. In the configuration elements in the following example embodiments, configuration elements which are not described in an independent claim will be described as optional configuration elements. In addition, sizes or size ratios of the configuration elements shown in drawings are not necessarily exact.

Each drawing is a schematic view in which emphasis, omission, or ratio adjustment is made as appropriate to represent the present invention, and is not necessarily shown strictly. In some cases, a shape, a positional relationship, and a ratio may be different from actual ones. In the drawings, the same reference numerals are assigned to substantially the same configurations, and repeated description thereof may be omitted or simplified in some cases.

In a circuit configuration of example embodiments of the present disclosure, a case of “being connected” includes not only a case where the configuration elements are directly connected by a connection terminal and/or a wiring conductor, but also a case where the configuration elements are electrically connected with a matching element such as an inductor and a capacitor, and a switch circuit interposed therebetween. A case of “being connected between A and B” means that the configuration elements are connected to both A and B between A and B.

In addition, terms representing a relationship between elements such as “parallel” and “perpendicular”, terms representing a shape of an element such as “rectangular”, and a numerical range not only represent strict meanings, but also mean a substantially equivalent range, for example, that an error of approximately several percent is included.

In addition, in the following example embodiments, a pass band of a filter is defined as a frequency band between two frequencies which are about 3 dB larger than a minimum value of an insertion loss inside the pass band, for example.

### EXAMPLE EMBODIMENTS

### 1. Configuration of Acoustic Wave Device 1 According to Example 1

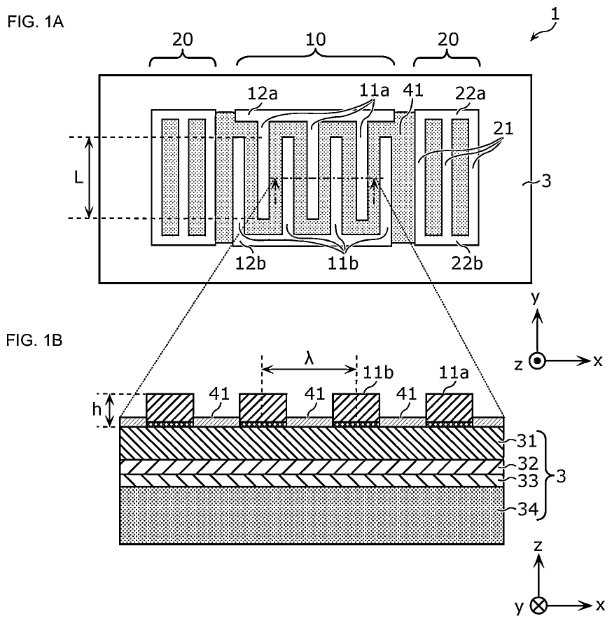

FIG. 1A is a plan view, and FIG. 1B is a sectional view of an acoustic wave device 1 according to Example 1. As shown in the drawing, the acoustic wave device 1 includes a substrate 3, an IDT electrode 10, a reflection electrode 20, and a dielectric film 41. The acoustic wave device 1 shown in FIG. 1 is provided to describe a typical structure of an acoustic wave resonator of the acoustic wave device 1, and the number and lengths of electrode fingers of the IDT electrode 10 are not limited thereto. As shown in FIG. 1A, the IDT electrode 10 and the reflection electrode 20 are provided on the substrate 3.

The substrate 3 has piezoelectricity, and includes a piezoelectric layer 31, a low acoustic velocity layer 32, a high acoustic velocity layer 33, and a support substrate 34.

The IDT electrode 10 and the reflection electrode 20 are provided on one surface of the piezoelectric layer 31. As the piezoelectric layer 31, for example, lithium tantalate, lithium niobate, or a material having the above-described material as a main component can be used. The film thickness of the piezoelectric layer 31 is about 400 nm, for example.

The high acoustic velocity layer 33 is provided on the other surface side of the piezoelectric layer 31, and a bulk wave acoustic velocity propagating through the high acoustic velocity layer 33 is higher than an acoustic velocity propagating through the piezoelectric layer 31. As a material of the high acoustic velocity layer 33, for example, a piezoelectric body such as aluminum nitride, lithium tantalate, lithium niobate, or crystal, a ceramic such as alumina, sapphire, magnesia, silicon nitride, silicon carbide, zirconia, cordierite, mullite, steatite, or forsterite, a dielectric such as diamond or glass, a semiconductor such as silicon or gallium nitride, or a resin, and alternatively, a material having the above-described materials as the main components can be used. The film thickness of the high acoustic velocity layer 33 is about 300 nm, for example.

The low acoustic velocity layer 32 is provided between the other main surface of the piezoelectric layer 31 and one main surface of the high acoustic velocity layer 33, and the acoustic velocity of the bulk wave propagating through the low acoustic velocity layer 32 is lower than that of the bulk wave propagating through the piezoelectric layer 31. This structure and a property that energy of an acoustic wave is essentially concentrated on a medium having a low acoustic velocity reduce or eliminate a possibility that surface acoustic wave energy leaks out from the IDT electrode. As the low acoustic velocity layer 32, for example, a dielectric body such as silicon oxide, glass, silicon oxynitride, lithium oxide, tantalum oxide, or a compound obtained by adding fluorine, carbon, or boron to silicon oxide, or a material having the above-described material as the main component can be used. The film thickness of the low acoustic velocity layer 32 is about 300 nm, for example.

The support substrate 34 is provided on the other main surface of the high acoustic velocity layer 33, and supports the IDT electrode 10, the piezoelectric layer 31, the low acoustic velocity layer 32, and the high acoustic velocity layer 33. As a material of the support substrate 34, for example, a piezoelectric body such as aluminum nitride, lithium tantalate, lithium niobate, or crystal, a ceramic such as alumina, sapphire, magnesia, silicon nitride, silicon carbide, zirconia, cordierite, mullite, steatite, or forsterite, a dielectric such as diamond or glass, a semiconductor such as silicon or gallium nitride, or a resin, and alternatively, a material having the above-described materials as the main components can be used.

According to the above-described multilayer structure of the substrate 3, a Q value in a resonant frequency and an anti-resonant frequency can be significantly increased, compared to a structure in the related art in which the piezoelectric substrate is used as a single layer. That is, since an acoustic wave resonator having a great Q value can be configured, a high frequency filter having a small insertion loss can be configured by using the acoustic wave resonator.

The high acoustic velocity layer 33 and the support substrate 34 may be combined as one high acoustic velocity support substrate. The high acoustic velocity support substrate supports the IDT electrode 10, the piezoelectric layer 31, and the low acoustic velocity layer 32. In the high acoustic velocity support substrate, the acoustic velocity of the bulk wave in the high acoustic velocity support substrate is higher than that of the acoustic wave such as a surface acoustic wave or a boundary acoustic wave propagating through the piezoelectric layer 31. The high acoustic velocity support substrate functions to confine the surface acoustic wave in a portion at which the piezoelectric layer 31 and the low acoustic velocity layer 32 are laminated, and prevent the surface acoustic wave from leaking down from the high acoustic velocity support substrate. As a material of the high acoustic velocity support substrate, for example, a piezoelectric body such as aluminum nitride, lithium tantalate, lithium niobate, or crystal, a ceramic such as alumina, sapphire, magnesia, silicon nitride, silicon carbide, zirconia, cordierite, mullite, steatite, forsterite, spinel, or sialon, a dielectric such as aluminum oxide, silicon oxynitride, diamond-like carbon (DLC), or diamond, or a semiconductor such as silicon, or alternatively, a material having the above-described materials as the main components can be used. The above-described spinel includes an aluminum compound including one or more elements selected from Mg, Fe, Zn, and Mn, and oxygen. Examples of the above-described spinel can include MgAl₂O₄, FeAl₂O₄, ZnAl₂O₄, or MnAl₂O₄.

In the present specification, the “main component of the material” means a component in which a ratio occupied by the material exceeds about 50% by weight. The main component may exist in any one state of single crystal, polycrystal, and amorphous, or in a mixed state thereof.

In addition, instead of the substrate 3, a structure in which a support substrate, an energy confinement layer, and a piezoelectric layer are laminated in this order may be provided. The IDT electrode 10 and the reflection electrode 20 are provided on the piezoelectric layer. As the piezoelectric layer, for example, a LiTaO₃ piezoelectric single crystal or piezoelectric ceramics is used. The support substrate supports the piezoelectric layer, the energy confinement layer, and the IDT electrode 10.

The energy confinement layer includes one layer or a plurality of layers, and the velocity of the bulk acoustic wave propagating through the at least one layer is higher than the velocity of the acoustic wave propagating through the vicinity of the piezoelectric layer. For example, the energy confinement layer may have a multilayer structure including the low acoustic velocity layer and the high acoustic velocity layer. The low acoustic velocity layer is a film in which the acoustic velocity of the bulk wave in the low acoustic velocity layer is lower than the acoustic velocity of the acoustic wave propagating through the piezoelectric layer. The high acoustic velocity layer is a film in which the acoustic velocity of the bulk wave in the high acoustic velocity layer is higher than the acoustic velocity of the acoustic wave propagating through the piezoelectric layer. The support substrate may be used as the high acoustic velocity layer.

In addition, the energy confinement layer may be an acoustic impedance layer having a configuration in which a low acoustic impedance layer having a relatively low acoustic impedance and a high acoustic impedance layer having a relatively high acoustic impedance are alternately laminated.

As shown in FIG. 1A, the IDT electrode 10 includes a plurality of electrode fingers 11a, a plurality of electrode fingers 11b, and busbar electrodes 12a and 12b.

The plurality of electrode fingers 11a are examples of a plurality of first electrode fingers, and are provided parallel to each other. The plurality of electrode fingers 11b are examples of a plurality of second electrode fingers, and are provided parallel to each other. The plurality of electrode fingers 11a and the plurality of electrode fingers 11b are provided in parallel to interdigitate with each other.

The busbar electrode 12a is an example of a first busbar electrode, and is configured to connect one ends of the plurality of electrode fingers 11a to each other. The busbar electrode 12a extends in a direction (x-axis direction) intersecting with an extending direction (y-axis direction in FIG. 1) of the plurality of electrode fingers 11a.

The busbar electrode 12b is an example of a second busbar electrode, and is configured to connect one ends of the plurality of electrode fingers 11b to each other. The busbar electrode 12b extends in the direction (x-axis direction) intersecting with the extending direction (y-axis direction in FIG. 1) of the plurality of electrode fingers 11b. The busbar electrode 12a and the busbar electrode 12b face each other with the plurality of electrode fingers 11a and the plurality of electrode fingers 11b interposed therebetween. The other end of the plurality of electrode fingers 11a faces the busbar electrode 12b, and the other end of the plurality of electrode fingers 11b faces the busbar electrode 12a.

The reflection electrodes 20 are provided on both sides of the IDT electrode 10 to be adjacent to the IDT electrode 10 in the direction (x-axis direction) perpendicular to the extending direction of the plurality of electrode fingers 11a and the plurality of electrode fingers 11b. The reflection electrode 20 is configured to confine a predetermined high frequency signal resonating in the IDT electrode 10 into the IDT electrode 10. The reflection electrode 20 includes a plurality of electrode fingers 21 and busbar electrodes 22a and 22b. The plurality of electrode fingers 21 are examples of a plurality of third electrode fingers, and are provided parallel to the plurality of electrode fingers 11a and the plurality of electrode fingers 11b. The busbar electrode 22a is an example of a third busbar electrode, and is configured to connect one ends of the plurality of electrode fingers 21 to each other. The busbar electrode 22b is an example of a fourth busbar electrode, and is configured to connect the other ends of the plurality of electrode fingers 21 to each other. The busbar electrode 22a and the busbar electrode 22b face each other with the plurality of electrode fingers 21 interposed therebetween. The reflection electrode 20 may be omitted from the acoustic wave device 1 according to this example.

As shown in FIG. 1B, for example, the IDT electrode 10 and the reflection electrode 20 have a multilayer structure including a close contact layer and a main electrode layer.

For example, the main electrode layer includes aluminum (Al) as the main component, and the film thickness is about 100 nm, for example. The close contact layer is provided between the main electrode layer and the piezoelectric layer 31, and is configured to improve a close contact degree of the main electrode layer to the substrate 3. For example, the close contact layer is formed of titanium (Ti), and the film thickness is about 10 nm, for example. The IDT electrode 10 and the reflection electrode 20 are not limited to the above-described multilayer structure. For example, both of these may be formed of metal or an alloy such as Ti, Al, Cu, Pt, Au, Ag, or Pd, and may be including a plurality of multilayer bodies formed of the above-described metal or alloy.

In order to improve or optimize propagation characteristics of the surface acoustic wave, it is preferable to optimally set (density×film thickness) of the IDT electrode 10. Since aluminum having low density and low resistance compared to a high density electrode material, the film thickness of the IDT electrode 10 can be set to be large. Therefore, the IDT electrode 10 having the low resistance can be provided. In addition, a relationship of lattice constants enables the films of the close contact layer (Ti) and the main electrode layer (Al) to be formed without interposing an amorphous dielectric film between the piezoelectric layer 31 and the IDT electrode 10. Accordingly, the IDT electrode 10 can be epitaxially grown. In this manner, a high performance high frequency filter using the acoustic wave device 1 and having excellent electric power handling capability can be realized.

The dielectric film 41 is an example of a first dielectric film, and is provided on the substrate 3. As shown in FIG. 1A, the dielectric film 41 is located only in a region where the plurality of electrode fingers 11a, the plurality of electrode fingers 11b, and the busbar electrodes 12a and 12b are not located, in a region between the busbar electrode 12a and the busbar electrode 12b in a plan view of the substrate 3, and is located only in a region where the plurality of electrode fingers 21 and the busbar electrodes 22a and 22b are not located, in the region between the busbar electrode 22a and the busbar electrode 22b in the plan view of the substrate 3.

In addition, as shown in FIG. 1B, the film thickness of the dielectric film 41 is smaller than a film thickness h of the plurality of electrode fingers 11a and the plurality of electrode fingers 11b.

In an acoustic wave device according to an example embodiment of the present invention, the phrase “the dielectric film 41 is located only in a region where an electrode A (including the electrode finger and the busbar electrode) is not located” means that the dielectric film 41 does not substantially overlap the electrode A in a plan view of the substrate 3. The phrase “the dielectric film 41 does not substantially overlap the electrode A” means that the dielectric film 41 may be in contact with the electrode A, and that an area where the dielectric film 41 and the electrode A overlap each other in the plan view of the substrate 3 is smaller than about 10% of a total area of the electrode A, for example.

As the dielectric film 41, silicon oxide, silicon nitride, aluminum oxide, yttrium oxide, tantalum oxide, titanium oxide, hafnium oxide, zirconium oxide, aluminum nitride, or sialon, or a material having the above-described materials as the main components can be used.

In the acoustic wave device 1 having the above-described configuration, a wavelength of the acoustic wave device 1 is defined by a wavelength λ which is a repeating period of the plurality of electrode fingers 11a or 11b of the IDT electrode 10 shown in FIG. 1B. In addition, an electrode finger pitch is about ½ of the wavelength λ, for example. In addition, as shown in FIG. 1A, an intersecting width L is a length in the y-axis direction of a region where the plurality of electrode fingers 11a and the plurality of electrode fingers 11b overlap each other when viewed in the direction (x-axis direction) parallel to the piezoelectric layer 31 and perpendicular to the extending direction (y-axis direction) of the plurality of electrode fingers 11a and the plurality of electrode fingers 11b.

According to the above-described configuration, it is possible to provide the small acoustic wave device 1 which can adjust the fractional band width without causing deterioration in the Q value. Hereinafter, an example in which the acoustic wave device 1 can have the above-described advantageous effect will be described.

### 2. Configuration of Acoustic Wave Device 500 According to Comparative Example

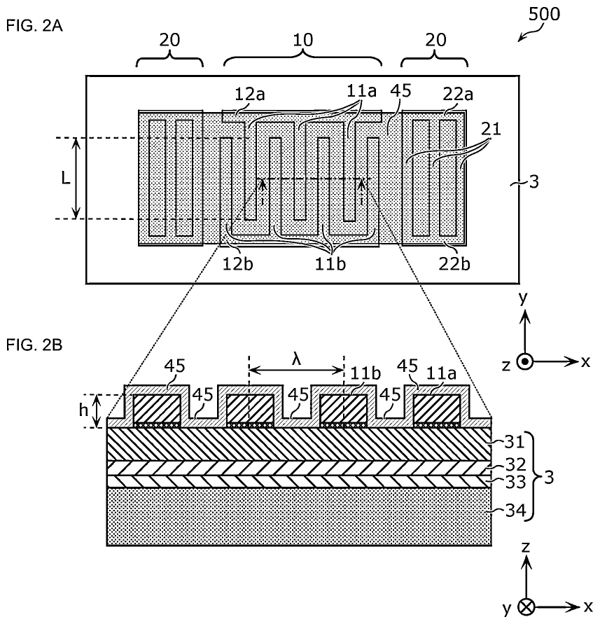

First, a configuration of an acoustic wave device 500 (in the related art) according to a comparative example will be described. FIGS. 2A and 2B are a plan view and a sectional view of the acoustic wave device 500 according to the comparative example. As shown in the drawing, the acoustic wave device 500 includes the substrate 3, the IDT electrode 10, the reflection electrode 20, and a dielectric film 45. The acoustic wave device 500 according to the comparative example is different from the acoustic wave device 1 according to Example 1 in a configuration only in a point that the dielectric film 45 is provided instead of the dielectric film 41. Hereinafter, in the acoustic wave device 500 according to the comparative example, the same configuration as that of the acoustic wave device 1 according to Example 1 will be omitted in the description, and different configurations will be mainly described.

The dielectric film 45 is provided on the substrate 3. As shown in FIG. 2A, the dielectric film 45 is provided in a region between the busbar electrode 12a and the busbar electrode 12b in a plan view of the substrate 3, and is provided in a region between the busbar electrode 22a and the busbar electrode 22b in a plan view of the substrate 3. The dielectric film 45 is also provided in a region overlapping the plurality of electrode fingers 11a, 11b, and 21 and the busbar electrodes 12a, 12b, 22a, and 22b in a plan view of the substrate 3. That is, the dielectric film 45 is formed to cover the IDT electrode 10 and the reflection electrode 20. As the dielectric film 45, for example, silicon oxide can be used.

According to the above-described configuration, the Q value can be ensured by the above-described multilayer structure of the substrate 3, but the fractional band width is limited to a specific range. In addition, when capacitance of the acoustic wave device 500 having the thin piezoelectric layer 31 needs to be ensured, the acoustic wave device 500 has to increase in size.

### 3. Resonance Characteristics of Acoustic Wave Device 1 According to Example 1

Here, resonance characteristics of the acoustic wave device 1 according to Example 1 will be described while being compared with resonance characteristics of the acoustic wave device 500 according to a comparative example.

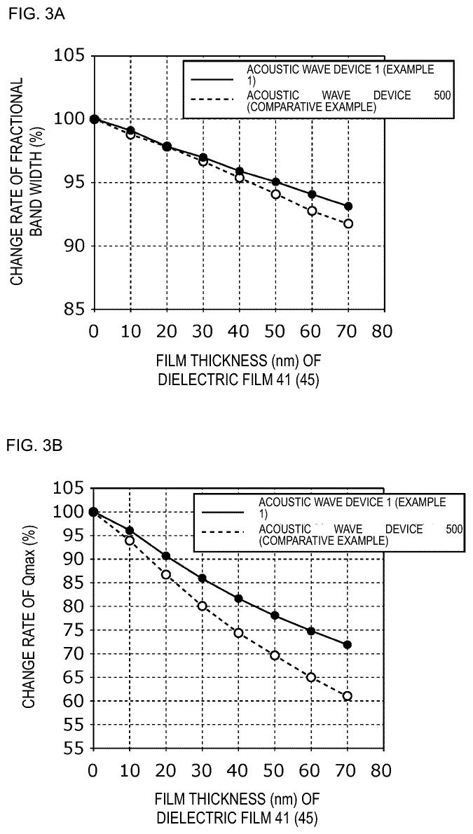

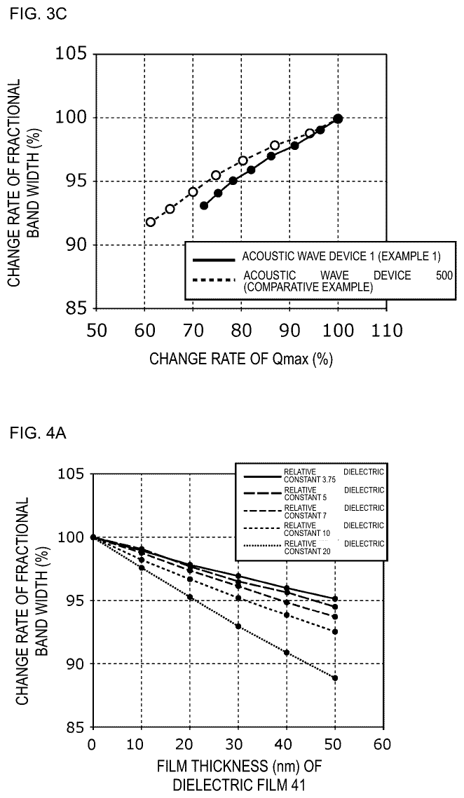

FIG. 3A is a graph showing a relationship between the film thickness of the dielectric film and a change rate of the fractional band width of the acoustic wave devices according to Example 1 and the comparative example. FIG. 3B is a graph showing a relationship between the film thickness of the dielectric film and a change rate of Qmax of the acoustic wave devices according to Example 1 and the comparative example. FIG. 3C is a graph showing a relationship between the change rate of the Qmax and a change rate of the fractional band width of the acoustic wave devices according to Example 1 and the comparative example. In each drawing, the change rate of the fractional band width represents a ratio of the fractional band width of the acoustic wave device according to Example 1 or the comparative example to the fractional band width when the dielectric film is not provided. In addition, in each drawing, the change rate of the Qmax represents a ratio of the Qmax of the acoustic wave device according to Example 1 or the comparative example to the Qmax when the dielectric film is not provided.

In addition, the resonance characteristics of the acoustic wave device 1 according to Example 1 and the acoustic wave device 500 according to the comparative example are evaluated as follows.
(1) Wavelength λ=2 μm
(2) Main electrode layer of IDT electrode 10: material_aluminum, film thickness_100 nm
(3) Close contact layer of IDT electrode 10: material_titanium, film thickness_10 nm
(4) Piezoelectric layer 31: material lithium tantalate, film thickness 400 nm
(5) Low acoustic velocity layer 32: material silicon oxide, film thickness_300 nm
(6) High acoustic velocity layer 33: material silicon nitride, film thickness_300 nm
(7) Support substrate 34: material silicon (111)

Example parameters are set as described above, and the resonance characteristics are evaluated by using a finite element method on an assumption that the acoustic wave device has an infinite periodic structure. In addition, as an index for evaluating the resonance characteristics, the fractional band width and the Qmax are set.

The fractional band width is represented by (anti-resonant frequency−resonant frequency)/resonant frequency. The anti-resonant frequency is a frequency at which an impedance of the acoustic wave device is maximized, and the resonant frequency is a frequency at which the impedance of the acoustic wave device is reduced or minimized.

Qmax is a maximum value obtained from the Q value (=(2 nfτ|Su|)/(1−|Su|²) (Non-Patent Document 1 “2008 IEEE International Ultrasonics Symposium Proceedings, p 431”). f is a frequency, and T is a group delay velocity.

In general, a loss caused by viscosity of the dielectric film in a minute region of the multilayer structure increases, compared to a loss caused by the dielectric film on a single crystal piezoelectric substrate. Therefore, as the film thickness of the dielectric film 41 of the acoustic wave device 1 according to Example 1 and the film thickness of the dielectric film 45 of the acoustic wave device 500 according to the comparative example decrease, the acoustic wave device can realize a low loss.

As shown in FIG. 3A, in both the acoustic wave device 1 according to Example 1 and the acoustic wave device 500 according to the comparative example, the fractional band width decreases as the film thickness of the dielectric film 41 (or 45) increases.

As shown in FIG. 3B, in both the acoustic wave device 1 according to Example 1 and the acoustic wave device 500 according to the comparative example, the Qmax decreases as the film thickness of the dielectric film 41 (or 45) increases.

However, as shown in FIG. 3C, the acoustic wave device 1 according to Example 1 can change the fractional band width by reducing or preventing a decrease in the Qmax (decrease in the change rate of the Qmax), compared to the acoustic wave device 500 according to the comparative example.

The film thickness of the dielectric film 41 is smaller than the film thickness of the plurality of electrode fingers 11a and the plurality of electrode fingers 11b.

That is, according to the acoustic wave device 1 in Example 1, since the dielectric film 41 thinner than the IDT electrode 10 is provided, it is possible to provide the small acoustic wave device which can adjust the fractional band width without causing deterioration in the Q value 1.

It is preferable that the film thickness of the dielectric film 41 is equal to or smaller than about 50% of the film thickness of the plurality of electrode fingers 11a and 11b, for example. According to this configuration, the change rate of the Qmax can be set to about 75% or higher, for example.

Furthermore, it is preferable that the film thickness of the dielectric film 41 is equal to or smaller than about 20% of the film thickness of the plurality of electrode fingers 11a and 11b, for example. According to this configuration, the change rate of the Qmax can be set to about 90% or higher, for example.

In the acoustic wave device 1 according to Example 1, it is preferable that a forming region of the dielectric film 41 is a region obtained by combining (1) only a region where the plurality of electrode fingers 11a, the plurality of electrode fingers 11b, and the busbar electrodes 12a and 12b are not located, in a region between the busbar electrode 12a and the busbar electrode 12b in a plan view of the substrate 3, (2) only a region where the plurality of electrode fingers 21 and the busbar electrodes 22a and 22b are not located, in a region between the busbar electrode 22a and the busbar electrode 22b in the plan view of the substrate 3, and (3) a region between the IDT electrode 10 and the reflection electrode 20.

According to this configuration, the dielectric film 41 has no structural discontinuous portion over the region from the IDT electrode 10 to the reflection electrode 20. Therefore, generation of unnecessary waves or a loss caused by the discontinuous portion can be reduced or prevented.

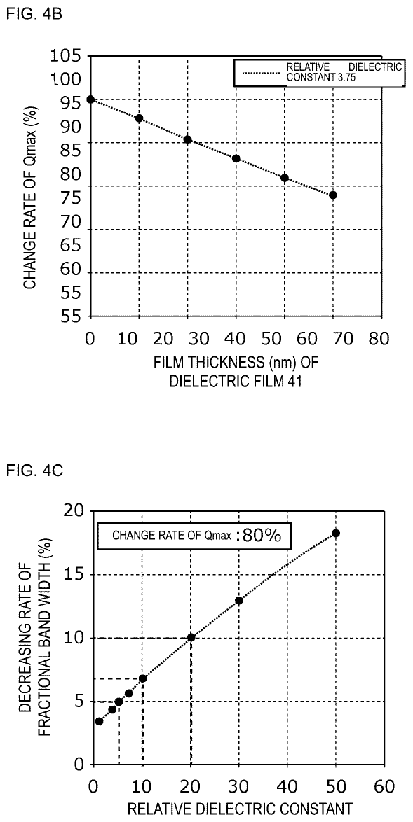

FIG. 4A is a graph showing a relationship between the film thickness of the dielectric film 41 and the change rate of the fractional band width when a relative dielectric constant of the dielectric film 41 is changed in the acoustic wave device 1 according to Example 1. FIG. 4B is a graph showing a relationship between the film thickness of the dielectric film 41 and the change rate of the Qmax when the relative dielectric constant of the dielectric film 41 is about 3.75 in the acoustic wave device 1 according to Example 1, for example. FIG. 4C is a graph showing a relationship between the relative dielectric constant and a decreasing rate of the fractional band width when the change rate of the Qmax is about 80% in the acoustic wave device 1 according to Example 1, for example.

As shown in FIG. 4A, in the acoustic wave device 1 according to Example 1, the fractional band width decreases as the film thickness of the dielectric film 41 increases. In addition, as the relative dielectric constant increases, a change amount of the fractional band width with respect to the film thickness of the dielectric film 41 increases, and the fractional band width can be adjusted with a thinner film thickness. In addition, the loss caused by the viscosity of the dielectric film in the minute region of the multilayer structure increases, compared to the loss caused by the dielectric film on the single crystal piezoelectric substrate. Therefore, the thinner dielectric film 41 is advantageous from a viewpoint of realizing a low loss. Furthermore, as shown in FIG. 4B, the Qmax decreases as the film thickness of the dielectric film 41 increases. Accordingly, the thinner dielectric film 41 is advantageous from a viewpoint of reducing or preventing deterioration in the Q value.

As shown in FIG. 4C, when the change rate of the Qmax is about 80%, it is necessary to set the relative dielectric constant needs to 5 or higher to decrease the fractional band width by about 5% (decreasing rate of fractional band width=about 5%), for example. When the change rate of the Qmax is about 80%, it is necessary to set the relative dielectric constant needs to 10 or higher to decrease the fractional band width by about 7% (decreasing rate of fractional band width=about 7%), for example. Furthermore, when the change rate of the Qmax is about 80%, it is necessary to set the relative dielectric constant needs to 20 or higher to decrease the fractional band width by about 10% (decreasing rate of fractional band width=about 10%), for example.

That is, since the relative dielectric constant is set to 5 or higher, 10 or higher, or 20 or higher, an adjustment effect of the fractional band width can increase in a state where a decrease in the Q value is small.

In addition, capacitance of the acoustic wave device 1 can be increased by raising the relative dielectric constant of the dielectric film 41. From this point of view, the acoustic wave device 1 can be reduced in size.

In bands 2, 3, 5, 7, 8, and 9 for Long Term Evolution (LTE) used in 3rd Generation Partnership Project (3GPP (Registered Trademark)) and bands n2, n3, n5, n7, n8, and n9 for 5th Generation (5G)-New Radio (NR), a difference in the frequency band between an uplink operating band and a downlink operating band is approximately 5%, for example.

When the acoustic wave device 1 according to this example is applied as an acoustic wave resonator of a high frequency filter in which the uplink operating band or the downlink operating band of the bands is used as a pass band, the relative dielectric constant of the dielectric film 41 is set to 5 or higher. Accordingly, a difference in pass band widths can be adjusted to approximately 5%, for example, while deterioration in the Q value of the acoustic wave resonator is reduced or prevented. In this manner, a transmission filter including the uplink operation band in the pass band and a reception filter including the downlink operation band in the pass band can be improved or optimized by using the acoustic wave device 1 according to this example.

In addition, in the band 28 for LTE and the band n28 for 5G-NR, the difference in the frequency bands between the uplink operating band and the downlink operating band is approximately 7%, for example. Therefore, the relative dielectric constant of the dielectric film 41 is set to 10 or higher. Accordingly, the difference in the pass band widths can be adjusted to approximately 7%, for example, while deterioration in the Q value of the acoustic wave resonator is reduced or prevented.

In addition, in the band 1 for LTE and the band n1 for 5G-NR, the difference in the frequency bands between the uplink operating band and the downlink operating band is approximately 10%, for example. Therefore, the relative dielectric constant of the dielectric film 41 is set to 20 or higher. Accordingly, the difference in the pass band widths can be adjusted to approximately 10%, for example, while deterioration in the Q value of the acoustic wave resonator is reduced or prevented.

Next, a relationship between the acoustic impedances of the IDT electrode 10 and the dielectric film 41 will be described.

When the acoustic impedance of the IDT electrode 10 is defined as R_{IDT}, the film thickness of the plurality of electrode fingers 11a and 11b is defined as t_{IDT}, the acoustic impedance of the dielectric film 41 provided between the plurality of electrode fingers 11a and the plurality of electrode fingers 11b is defined as R_{DIE}, and the film thickness of the dielectric film 41 is defined as t_{DIE}, a relational expression of Expression 1 is satisfied.

$${R}_{IDT} \times {t}_{IDT} > {R}_{DIE} \times {t}_{DIE} \qquad ( Expression 1 )$$

Here, the acoustic impedance is expressed by (ρ×E)^{1/2}, where ρ is the density and E is the Young's modulus.

When the acoustic impedance R_{IDT} of the IDT electrode 10 becomes smaller than the acoustic impedance R_{DIE} of the dielectric film 41, the surface acoustic wave leaks out from the acoustic wave resonator. Therefore, the resonance characteristics of the acoustic wave device deteriorate. In contrast, since the film thickness t_{DIE} of the dielectric film 41 is set to be thinner than the film thickness t_{IDT} of the IDT electrode 10, the leakage of the surface acoustic wave can be reduced or prevented, and the acoustic wave device 1 having high characteristics can be obtained.

For example, when the IDT electrode 10 is formed of aluminum (E=70 GPa, ρ=2.7 g/cm³) and the dielectric film 41 is formed of silicon oxide (E=72 GPa, ρ=2.2 g/cm³), the acoustic impedance R_{IDT} and the acoustic impedance R_{DIE} have values extremely close to each other. Therefore, it is preferable that the dielectric film 41 is set to be thinner than the IDT electrode 10. In addition, when the relative dielectric constant of the dielectric film 41 is high, the dielectric film 41 has the higher impedance than that of silicon oxide (SiO₂). Therefore, it is preferable that the dielectric film 41 is thinner than the IDT electrode 10.

When the IDT electrode 10 is a multilayer body having a layer A and a layer B and the dielectric film 41 is a multilayer body having a layer C and a layer D, the relationship is defined as follows. When the acoustic impedance of the layer A is defined as R_{A}, the film thickness of the layer A is defined as t_{A}, the acoustic impedance of the layer B is defined as R_{B}, the film thickness of the layer B is defined as t_{B}, the acoustic impedance of the layer C provided between the plurality of electrode fingers 11a and the plurality of electrode fingers 11b is defined as R_{C}, the film thickness of the layer C is defined as t_{C}, the acoustic impedance of the layer D provided between the plurality of electrode fingers 11a and the plurality of electrode fingers 11b is defined as R_{D}, and the film thickness of the layer D is defined as t_{D}, a relational expression of Expression 2 is satisfied.

$${R}_{A} \times {t}_{A} + {R}_{B} \times {t}_{B} > {R}_{C} \times {t}_{C} + {R}_{D} \times {t}_{D} \qquad ( Expression 2 )$$

That is, when the IDT electrode 10 is a multilayer body including n layers (n is a natural number) and the dielectric film 41 is a multilayer body including m layers (m is a natural number), the relationship is defined as follows. When the acoustic impedance of the k-th layer of the IDT electrode 10 is defined as R_{IDTk}, the film thickness of the k-th layer of the IDT electrode 10 is defined as t_{IDTk}, the acoustic impedance of the k-th layer of the dielectric film 41 provided between the plurality of electrode fingers 11a and the plurality of electrode fingers 11b is defined as R_{DIEk}, and the film thickness of the k-th layer of the dielectric film 41 provided between the plurality of electrode fingers 11a and the plurality of electrode fingers 11b is defined as t_{DIE}k, a relational expression of Expression 3 is satisfied.

$${\sum }_{k = 1}^{n} {R}_{IDTk} \times {t}_{IDTk} > {\sum }_{k = 1}^{m} {R}_{DIEk} \times {t}_{DIEk} \qquad ( Expression 3 )$$

A material of the dielectric film 41 is not limited to silicon oxide. Hereinafter, the material of the dielectric film 41 will be described.

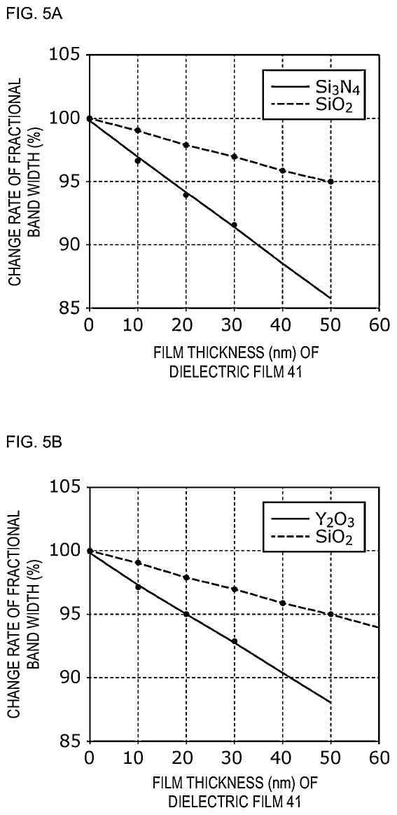

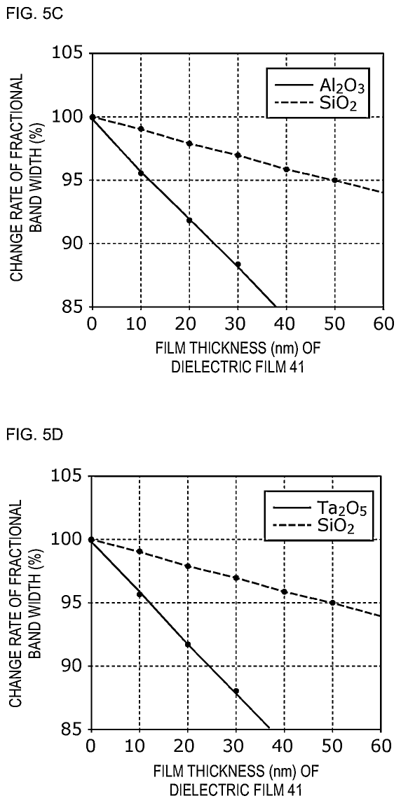

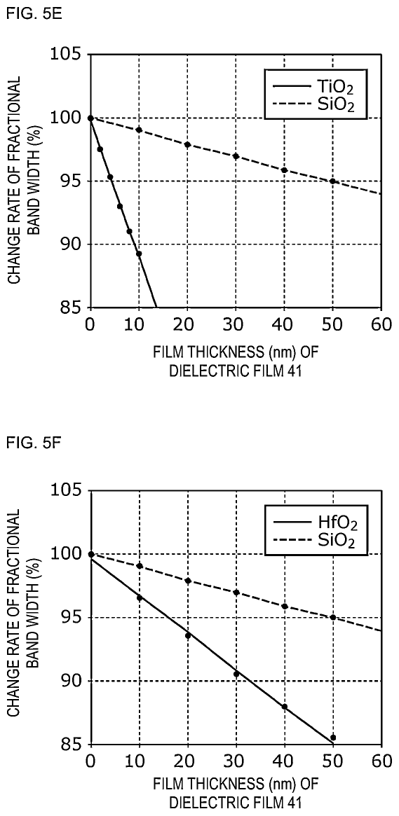

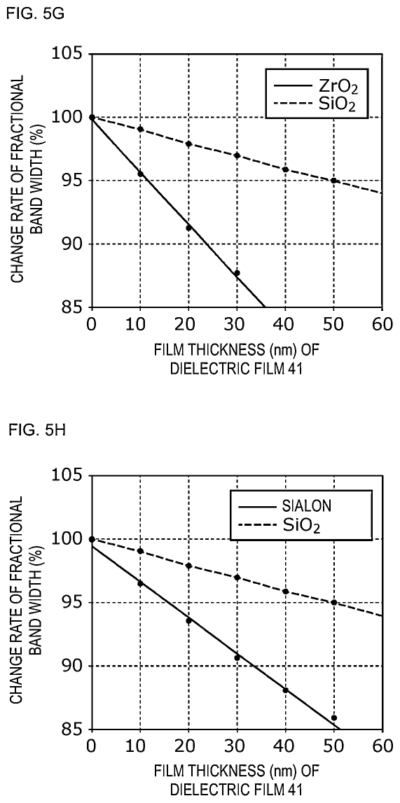

FIG. 5A is a graph showing a relationship between the film thickness of the dielectric film 41 and the change rate of the fractional band width when the dielectric film 41 is silicon nitride or silicon oxide. FIG. 5B is a graph showing a relationship between the film thickness of the dielectric film 41 and the change rate of the fractional band width when the dielectric film 41 is yttrium oxide or silicon oxide. FIG. 5C is a graph showing a relationship between the film thickness of the dielectric film 41 and the change rate of the fractional band width when the dielectric film 41 is aluminum oxide or silicon oxide. FIG. 5D is a graph showing a relationship between the film thickness of the dielectric film 41 and the change rate of the fractional band width when the dielectric film 41 is tantalum oxide or silicon oxide. FIG. 5E is a graph showing a relationship between the film thickness of the dielectric film 41 and the change rate of the fractional band width when the dielectric film 41 is titanium oxide or silicon oxide. FIG. 5F is a graph showing a relationship between the film thickness of the dielectric film 41 and the change rate of the fractional band width when the dielectric film 41 is hafnium oxide or silicon oxide. FIG. 5G is a graph showing a relationship between the film thickness of the dielectric film 41 and the change rate of the fractional band width when the dielectric film 41 is zirconium oxide or silicon oxide. FIG. 5H is a graph showing a relationship between the film thickness of the dielectric film 41 and the change rate of the fractional band width when the dielectric film 41 is sialon or silicon oxide.

As shown in FIGS. 5A to 5H, when the dielectric film 41 is silicon nitride, yttrium oxide, aluminum oxide, tantalum oxide, titanium oxide, hafnium oxide, zirconium oxide, or sialon, even in any case, it is understood that an adjustment range of the fractional band width can be widened, compared to when the dielectric film 41 is silicon oxide.

High dielectric constant materials such as silicon nitride (SiN), yttrium oxide (Y₂O₃), aluminum oxide (Al₂O₃), tantalum oxide (Ta₂O₅), hafnium oxide (HfO₂), zirconium oxide (ZrO₂), a sialon, or aluminum nitride (AlN) are used as the material of the dielectric film 41. Accordingly, the fractional band width of the acoustic wave device 1 can be adjusted with a configuration in which the dielectric film 41 is thin.

Furthermore, materials having higher thermal conductivity than that of the material of the piezoelectric layer 31, such as aluminum oxide (Al₂O₃) and yttrium oxide (Y₂O₃) are used as the material of the dielectric film 41. Accordingly, heat radiation is improved when the acoustic wave device 1 is used as the high frequency filter. Therefore, electric power handling capability of the high frequency filter can be improved.

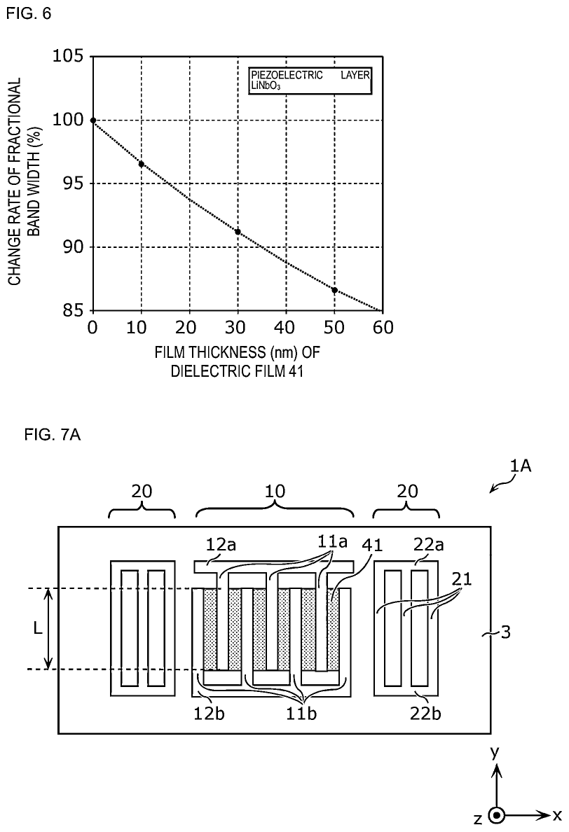

Next, the material of the piezoelectric layer 31 will be described. FIG. 6 is a graph showing a relationship between the film thickness of the dielectric film 41 and the change rate of the fractional band width when the piezoelectric layer 31 of the acoustic wave device 1 according to Example 1 is lithium niobate.

The resonance characteristics shown in FIG. 6 are obtained by setting each parameter of the acoustic wave device 1 according to the following examples.
(1) Wavelength λ=2 μm
(2) Main electrode layer of IDT electrode 10: material_aluminum, film thickness_160 nm
(3) Close contact layer of IDT electrode 10: material_titanium, film thickness 12 nm
(4) piezoelectric layer 31: material lithium niobate, film thickness 1100 nm
(5) Low acoustic velocity layer 32: material silicon oxide, film thickness_210 nm
(6) High acoustic velocity layer 33: material silicon nitride, film thickness_380 nm
(7) Support substrate 34: material silicon (111)

As shown in FIG. 6, even when the material of the piezoelectric layer 31 is lithium niobate, the fractional band width can be adjusted as when the material of the piezoelectric layer 31 is lithium tantalate. For example, the material of the piezoelectric layer 31 may be crystal, aluminum nitride, or PZT, and the same advantageous effect as that when lithium tantalate or lithium niobate is used as the material of the piezoelectric layer 31 can be achieved.

### 4. Configuration of Acoustic Wave Device 1A According to Modification Example 1

In an acoustic wave device according to an example embodiment of the present invention, a forming region of the dielectric film 41 is not limited to a forming region shown in FIG. 1.

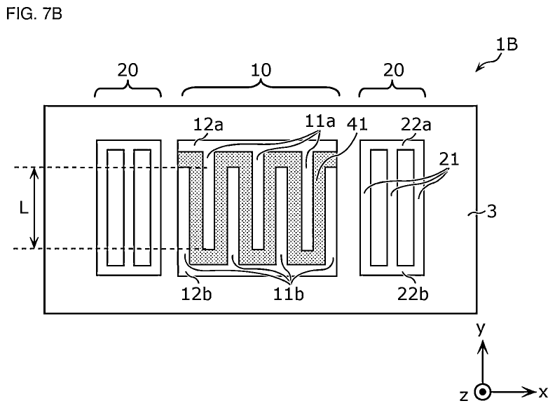

FIG. 7A is a plan view of an acoustic wave device 1A according to Modification Example 1. As shown in the drawing, the acoustic wave device 1A includes the substrate 3, the IDT electrode 10, the reflection electrode 20, and the dielectric film 41. The acoustic wave device 1A according to the present modification example is different in the forming region of the dielectric film 41, compared to the acoustic wave device 1 according to Example 1. Therefore, hereinafter, in the acoustic wave device 1A according to the present modification example, the same configuration as that of the acoustic wave device 1 according to Example 1 will be omitted in the description, and different configurations will be mainly described.

The dielectric film 41 is an example of a first dielectric film, and is provided on the substrate 3. As shown in FIG. 7A, the dielectric film 41 is provided on the piezoelectric layer 31, and is located only in a region where the plurality of electrode fingers 11a and 11b are not located in a region (region of an intersecting width L in FIG. 7A) where the plurality of electrode fingers 11a and the plurality of electrode fingers 11b overlap each other when viewed in a direction (x-axis direction) parallel to the piezoelectric layer 31 and perpendicular to the extending direction (y-axis direction) of the plurality of electrode fingers 11a and the plurality of electrode fingers 11b.

The film thickness of the dielectric film 41 is smaller than the film thickness of the plurality of electrode fingers 11a and 11b.

According to this configuration, the fractional band width can be adjusted without decreasing capacitance per unit area of the acoustic wave device 1A using a multilayer substrate structure. In addition, since the dielectric film 41 is located only between the electrode fingers, the capacitance per unit area can be increased, compared to the acoustic wave device in the related art in which the dielectric film 41 is not located, and the acoustic wave device 1A can be reduced in size. Furthermore, compared to the acoustic wave device in the related art in which the dielectric film is located on the entirety including the electrode fingers, the fractional band width can be adjusted without causing deterioration in the Q value of the acoustic wave device.

### 5. Configuration of Acoustic Wave Device 1B According to Modification Example 2

FIG. 7B is a plan view of an acoustic wave device 1B according to Modification Example 2. As shown in the drawing, the acoustic wave device 1B includes the substrate 3, the IDT electrode 10, the reflection electrode 20, and the dielectric film 41. The acoustic wave device 1B according to the present modification example is different from the acoustic wave device 1 according to Example 1 in a forming region of the dielectric film 41. Therefore, hereinafter, in the acoustic wave device 1B according to the present modification example, the same configuration as that of the acoustic wave device 1 according to Example 1 will be omitted in the description, and different configurations will be mainly described.

The dielectric film 41 is an example of a first dielectric film, and is provided on the substrate 3. As shown in FIG. 7B, the dielectric film 41 is provided on the piezoelectric layer 31, and is located only in a region where the plurality of electrode fingers 11a and 11b and the busbar electrodes 12a and 12b are not located, in a region between the busbar electrode 12a and the busbar electrode 12b in a plan view of the substrate 3.

According to this configuration, the fractional band width can be adjusted without decreasing the capacitance per unit area of the acoustic wave device 1B using the multilayer substrate structure. In addition, since the dielectric film 41 is pinched only between the electrode fingers, the capacitance per unit area can be increased, compared to the acoustic wave device in the related art in which the dielectric film 41 is not located, and the acoustic wave device 1B can be reduced in size. Furthermore, compared to the acoustic wave device in the related art in which the dielectric film is provided on the entirety including the electrode fingers, the fractional band width can be adjusted without causing deterioration in the Q value of the acoustic wave device.

### 6. Configuration of Acoustic Wave Device 1C According to Example 2

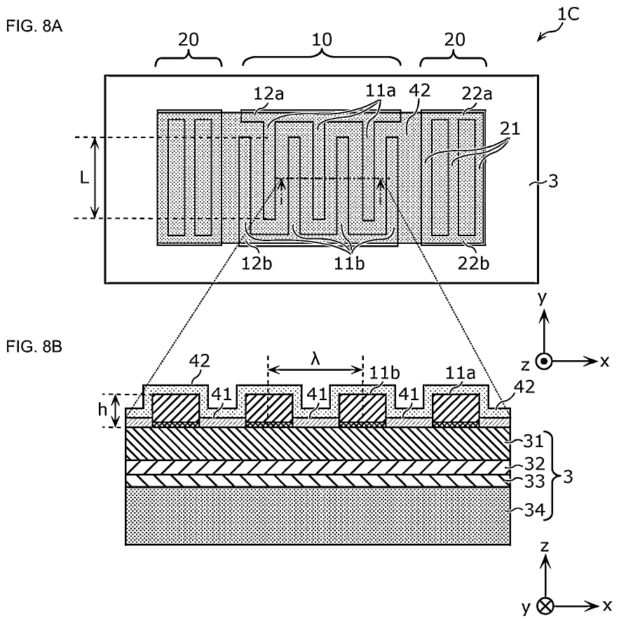

FIG. 8A is a plan view, and FIG. 8B is a sectional view of an acoustic wave device 1C according to Example 2. As shown in the drawing, the acoustic wave device 1C includes the substrate 3, the IDT electrode 10, the reflection electrode 20, and dielectric films 41 and 42. The acoustic wave device 1C according to this example is different from the acoustic wave device 1 according to Example 1 in that a dielectric film 42 is added. Therefore, hereinafter, in the acoustic wave device 1C according to this example, the same configuration as that of the acoustic wave device 1 according to Example 1 will be omitted in the description, and different configurations will be mainly described.

The dielectric film 41 is an example of a first dielectric film, and is provided on the substrate 3. The dielectric film 41 is located only in the region where the plurality of electrode fingers 11a and 11b and the busbar electrodes 12a and 12b are not located, in the region between the busbar electrode 12a and the busbar electrode 12b in the plan view of the substrate 3, and is located only in the region where the plurality of electrode fingers 21 and the busbar electrodes 22a and 22b are not located, in the region between the busbar electrode 22a and the busbar electrode 22b in the plan view of the substrate 3.

In addition, as shown in FIG. 8B, the film thickness of the dielectric film 41 is smaller than the film thickness h of the plurality of electrode fingers 11a and 11b.

The dielectric film 42 is an example of the second dielectric film, and is provided on the dielectric film 41, the plurality of electrode fingers 11a, 11b, and 22, and the busbar electrodes 12a, 12b, 22a, and 22b. The dielectric film 42 and the dielectric film 41 have different materials or compositions.

According to this configuration, since the dielectric film 42 is provided, it is possible to reduce or prevent a short-circuit failure caused by dust from an outer side portion between the electrode fingers, and characteristic deterioration caused by humidity.

For example, the dielectric film 42 is any one of silicon oxide, silicon nitride, or silicon oxynitride.

It is preferable that the relative dielectric constant of the dielectric film 42 is lower than the relative dielectric constant of the dielectric film 41. According to this configuration, deterioration in the Q value of the acoustic wave device 1C can be reduced or prevented by the dielectric film 42.

It is preferable that the film thickness of the dielectric film 42 is smaller than the film thickness of the dielectric film 41. According to this configuration, deterioration in the Q value of the acoustic wave device 1C can be reduced or prevented by the dielectric film 42. The anti-resonant frequency and the resonant frequency of the acoustic wave device 1C can be adjusted by adjusting the film thickness of the dielectric film 42.

### 7. Configurations of Acoustic Wave Resonator, High Frequency Filter, and Filter Circuit Using Acoustic Wave Device 1

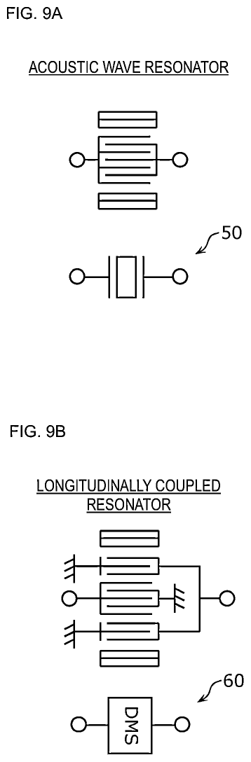

FIG. 9A is a view schematically showing an electrode configuration of the acoustic wave resonator according to an example embodiment, and is a view schematically showing the acoustic wave resonator. The acoustic wave device 1 according to Example 1 is applicable as an acoustic wave resonator 50 shown in FIG. 9A.

FIG. 9B is a view schematically showing an electrode configuration of the longitudinally coupled resonator according to the present example embodiment, and is a view schematically showing the longitudinally coupled resonator. The acoustic wave device 1 according to Example 1 is applicable as a longitudinally coupled resonator (double mode SAW: DMS) 60 shown in FIG. 9B.

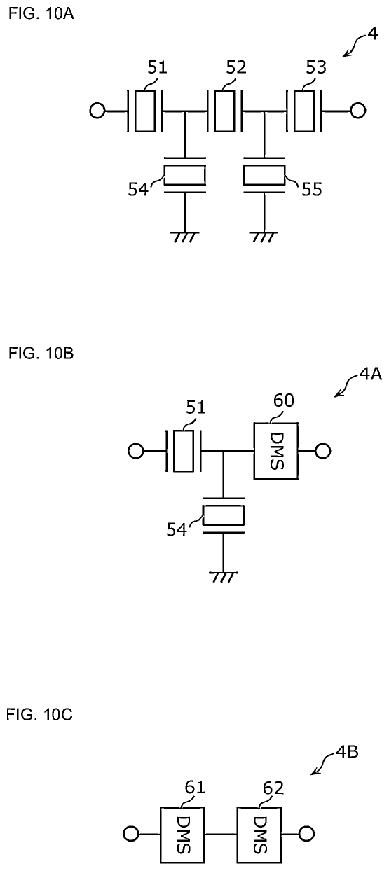

FIG. 10A is a circuit configuration diagram of a ladder-type high frequency filter 4 according to the present example embodiment. As shown in the drawing, the high frequency filter 4 includes series arm resonators 51, 52, and 53 connected in series to a path to couple two input/output terminals, and parallel arm resonators 54 and 55 connected between the path to couple the series arm resonators 51, 52, and 53 and a ground. Each of the series arm resonators 51 to 53 and the parallel arm resonators 54 and 55 is an acoustic wave resonator using the acoustic wave device 1 according to Example 1. According to the above-described configuration, the high frequency filter 4 defines the ladder-type high frequency filter.

According to this configuration, the fractional band width of the acoustic wave device 1 of the high frequency filter 4 can be adjusted without causing deterioration in the Q value. Therefore, the high frequency filter 4 having an improved or optimized bandpass characteristic can be provided.

In the high frequency filter 4, the dielectric films 41 (first dielectric films) of at least two of the series arm resonators 51 to 53 and the parallel arm resonators 54 and 55 may have different film thicknesses, materials, or compositions. According to this configuration, the acoustic wave resonators having different fractional band widths can be combined. Therefore, for example, the high frequency filter 4 having excellent steepness and a wide band can be provided.

FIG. 10B is a circuit configuration diagram of a high frequency filter 4A including the longitudinally coupled resonator according to the present example embodiment. As shown in the drawing, the high frequency filter 4A includes the series arm resonator 51 and a longitudinally coupled resonator 60 which are connected in series to the path to couple two input/output terminals, and the parallel arm resonator 54 connected between the path to couple the series arm resonator 51 and the longitudinally coupled resonator 60 and the ground. Each of the series arm resonator 51, the parallel arm resonator 54, and the longitudinally coupled resonator 60 is the acoustic wave resonator including the acoustic wave device 1 according to Example 1. According to the above-described configuration, the high frequency filter 4A defines the longitudinally coupled high frequency filter.

According to this configuration, the fractional band width of the acoustic wave device 1 of the high frequency filter 4A can be adjusted without causing deterioration in the Q value, so that the high frequency filter 4A having an improved or optimized bandpass characteristic can be provided.

In the high frequency filter 4A, the dielectric films 41 (first dielectric films) of at least two of the series arm resonator 51, the parallel arm resonator 54, and the longitudinally coupled resonator 60 may have different film thicknesses, materials, or compositions. According to this configuration, the acoustic wave resonators having different fractional band widths can be combined. Therefore, for example, the high frequency filter 4A having excellent steepness and a wide band can be provided.

FIG. 10C is a circuit configuration diagram of a high frequency filter 4B including a plurality of longitudinally coupled resonators according to the present example embodiment. As shown in the drawing, the high frequency filter 4B includes longitudinally coupled resonators 61 and 62 connected in series to the path to couple two input/output terminals. Each of the longitudinally coupled resonators 61 and 62 is the acoustic wave resonator using the acoustic wave device 1 according to Example 1. According to the above-described configuration, the high frequency filter 4B defines a longitudinally coupled high frequency filter.

According to this configuration, the fractional band width of the acoustic wave device 1 of the high frequency filter 4B can be adjusted without causing deterioration in the Q value. Therefore, the high frequency filter 4B having an improved or optimized bandpass characteristic can be provided.

In the high frequency filter 4B, the dielectric films 41 (first dielectric films) of the respective longitudinally coupled resonators 61 and 62 may have different film thicknesses, materials, or compositions. According to this configuration, the acoustic wave resonators having different fractional band widths can be combined. Therefore, for example, the high frequency filter 4B having excellent steepness and a wide band can be provided.

In addition, the filter circuit according to the present example embodiment includes a plurality of the high frequency filters which are any of the high frequency filters 4, 4A, and 4B. Here, the plurality of high frequency filters provided in the filter circuit share one substrate 3. In addition, the dielectric film 41 (first dielectric film) of a first high frequency filter in the above-described plurality of high frequency filters and the dielectric film (first dielectric film) of a second high frequency filter in the above-described plurality of high frequency filters have different film thicknesses, materials, or compositions.

According to this configuration, the plurality of high frequency filters having different pass band widths can be provided on the same substrate. Therefore, the filter circuit including the plurality of high frequency filters can be reduced in size.

### 8. Advantageous Effects

As described above, the acoustic wave device 1 according to Example 1, the acoustic wave device 1B according to Modification Example 2, and the acoustic wave device 1C according to Example 2 include the substrate 3, the IDT electrode 10 on the substrate 3, and the dielectric film 41 on the substrate 3. The substrate 3 includes the piezoelectric layer 31, the low acoustic velocity layer 32, and the high acoustic velocity layer 33 in this order. The IDT electrode 10 includes the plurality of electrode fingers 11a and 11b, the busbar electrode 12a that connects the plurality of electrode fingers 11a, and the busbar electrode 12b that connects the plurality of electrode fingers 11b. On the piezoelectric layer 31, the dielectric film 41 is located only in a region where the plurality of electrode fingers 11a and 11b and the busbar electrodes 12a and 12b are not located, in a region between the busbar electrode 12a and the busbar electrode 12b in a plan view of the substrate 3, and is located only in a region where the busbar electrode 12a and the busbar electrode 12b are not located. The film thickness of the dielectric film 41 is smaller than the film thickness of the plurality of electrode fingers 11a and 11b.

According to this configuration, the fractional band width can be adjusted without reducing capacitance per unit area of the acoustic wave device using a multilayer substrate structure. In addition, since the dielectric film 41 is pinched only between the electrode fingers, capacitance per unit area can be increased, compared to the acoustic wave device in the related art in which the dielectric film 41 is not provided, and the acoustic wave device can be reduced in size. Furthermore, compared to the acoustic wave device in the related art in which the dielectric film is provided on the entirety including the electrode fingers, the fractional band width can be adjusted without causing deterioration in the Q value of the acoustic wave device.

In addition, for example, the acoustic wave device 1 according to Example 1 and the acoustic wave device 1C according to Example 2 further include the reflection electrode 20 adjacent to the IDT electrode 10 in a direction perpendicular to the extending direction of the plurality of electrode fingers 11a and 11b. The reflection electrode 20 includes the plurality of electrode fingers 21 parallel to the plurality of electrode fingers 11a and 11b, the busbar electrode 22a that connects one ends of the plurality of electrode fingers 21 to each other, and the busbar electrode 22b that connects the other ends of the plurality of electrode fingers 21 to each other. On the piezoelectric layer 31, the dielectric film 41 is located only in a region where the plurality of electrode fingers 11a and 11b and the busbar electrodes 12a and 12b are not located, in a region between the busbar electrode 12a and the busbar electrode 12b in a plan view of the substrate 3. On the piezoelectric layer 31, the dielectric film 41 is located only in a region where the plurality of electrode fingers 21 and the busbar electrodes 22a and 22b are not located, in a region between the busbar electrode 22a and the busbar electrode 22b in the plan view of the substrate 3.

According to this configuration, the fractional band width can be adjusted without reducing capacitance per unit area of the acoustic wave device using a multilayer substrate structure. In addition, since the dielectric film 41 is pinched only between the electrode fingers, capacitance per unit area can be increased, compared to the acoustic wave device in the related art in which the dielectric film 41 is not provided, and the acoustic wave device can be reduced in size. Furthermore, compared to the acoustic wave device in the related art in which the dielectric film is provided on the entirety including the electrode fingers, the fractional band width can be adjusted without causing deterioration in the Q value of the acoustic wave device.

In addition, for example, in the acoustic wave devices 1, 1A, 1B, and 1C, when the acoustic impedance of the IDT electrode 10 is defined as R_{IDT}, the film thickness of the plurality of electrode fingers 11a and 11b is defined as t_{IDT}, the acoustic impedance of the dielectric film 41 provided between the plurality of electrode fingers 11a and the plurality of electrode fingers 11b is defined as R_{DIE}, and the film thickness of the dielectric film 41 is defined as t_{DIE}, a relationship of R_{IDT}×t_{IDT}>R_{DIE}×t_{DIE} is satisfied.

According to this configuration, a leakage of the surface acoustic wave can be reduced or prevented, and the acoustic wave device having high characteristics can be obtained.

In addition, for example, in the acoustic wave devices 1, 1A, 1B, and 1C, the IDT electrode 10 is a multilayer body including n layers (n is a natural number), and the dielectric film 41 is a multilayer body including m layers (m is a natural number). When the acoustic impedance of the k-th layer of the IDT electrode 10 is defined as R_{IDTk}, the film thickness of the k-th layer of the IDT electrode 10 is defined as t_{IDTk}, the acoustic impedance of the k-th layer of the dielectric film 41 between the plurality of electrode fingers 11a and the plurality of electrode fingers 11b is defined as R_{DIEk}, and the film thickness of the k-th layer of the dielectric film 41 is defined as t_{DIEk}, a relationship of

$${\sum }_{k = 1}^{n} {R}_{IDTk} \times {t}_{IDTk} > {\sum }_{k = 1}^{m} {R}_{DIEk} \times {t}_{DIEk}$$

is satisfied.

According to this configuration, when each of the IDT electrode 10 and the dielectric film 41 includes a multilayer body, a leakage of surface acoustic waves can be reduced or prevented, and the acoustic wave device having high characteristics can be obtained.

In addition, for example, in the acoustic wave devices 1, 1A, 1B, and 1C, the relative dielectric constant of the dielectric film 41 is 5 or higher.

According to this configuration, in a state where the change rate of the Qmax is about 80%, the fractional band width can be adjusted by about 5%, for example.

In addition, for example, in the acoustic wave devices 1, 1A, 1B, and 1C, the relative dielectric constant of the dielectric film 41 is 10 or higher, for example.

According to this configuration, in a state where the change rate of the Qmax is about 80%, the fractional band width can be adjusted by about 7%, for example.

In addition, for example, in the acoustic wave devices 1, 1A, 1B, and 1C, the film thickness of the dielectric film 41 is equal to or smaller than about 50% of the film thickness of the plurality of electrode fingers 11a and 11b, for example.

According to this configuration, in a state where the change rate of the Qmax is about 75% or higher, for example, the fractional band width can be adjusted.

In addition, for example, in the acoustic wave devices 1, 1A, 1B, and 1C, the film thickness of the dielectric film 41 is equal to or smaller than about 20% of the film thickness of the plurality of electrode fingers 11a and 11b, for example.

According to this configuration, in a state where the change rate of the Qmax is about 90% or higher, for example, the fractional band width can be adjusted.

In addition, for example, in the acoustic wave devices 1, 1A, 1B, and 1C, the piezoelectric layer 31 includes either of lithium tantalate or lithium niobate.

In addition, for example, in the acoustic wave devices 1, 1A, 1B, and 1C, the dielectric film 41 includes any one of silicon nitride, aluminum oxide, yttrium oxide, tantalum oxide, titanium oxide, hafnium oxide, zirconium oxide, aluminum nitride, or sialon.

According to this configuration, the adjustment range of the fractional band width can be widened, compared to when the dielectric film 41 is formed of silicon oxide.

In addition, for example, in the acoustic wave devices 1, 1A, 1B, and 1C, the IDT electrode 10 includes a main electrode layer including aluminum and a close contact layer between the main electrode layer and the piezoelectric layer 31.

According to this configuration, since aluminum having low density and low resistance is used as the main electrode layer, the film thickness of the IDT electrode 10 can be set to be large. Therefore, the IDT electrode 10 having the low resistance can be provided.

In addition, for example, in the acoustic wave devices 1, 1A, 1B, and 1C, the thermal conductivity of the dielectric film 41 is higher than the thermal conductivity of the piezoelectric layer 31.

According to this configuration, heat radiation is improved when the acoustic wave device is used as the high frequency filter. Therefore, electric power handling capability of the high frequency filter using the acoustic wave device can be improved.

In addition, for example, the acoustic wave device 1C further includes the dielectric film 42 on the IDT electrode 10 and the dielectric film 41, and including a material or a composition different from that of the dielectric film 41.

According to this configuration, since the dielectric film 42 is provided, it is possible to reduce or prevent a short-circuit failure caused by dust from the outer side portion between the electrode fingers, and characteristic deterioration caused by humidity.

In addition, for example, in the acoustic wave device 1C, the relative dielectric constant of the dielectric film 42 is lower than the relative dielectric constant of the dielectric film 41.

According to this configuration, deterioration in the Q value of the acoustic wave device 1C can be reduced or prevented by the dielectric film 42.

In addition, for example, in the acoustic wave device 1C, the film thickness of the dielectric film 42 is smaller than the film thickness of the dielectric film 41.

According to this configuration, deterioration in the Q value of the acoustic wave device 1C can be reduced or prevented by the dielectric film 42.

In addition, for example, in the acoustic wave device 1C, the dielectric film 42 includes any one of silicon oxide, silicon nitride, or silicon oxynitride.

In addition, the acoustic wave device 1 according to Example 1, the acoustic wave device 1A according to Modification Example 1, the acoustic wave device 1B according to Modification Example 2, and the acoustic wave device 1C according to Example 2 include the substrate 3, the IDT electrode 10 on the substrate 3, and the dielectric film 41 on the substrate 3. The substrate 3 includes the piezoelectric layer 31, the low acoustic velocity layer 32, and the high acoustic velocity layer 33 in this order. The IDT electrode 10 includes the plurality of electrode fingers 11a and 11b, the busbar electrode 12a that connects the plurality of electrode fingers 11a, and the busbar electrode 12b that connects the plurality of electrode fingers 11b. On the piezoelectric layer 31, the dielectric film 41 is located only in a region where the plurality of electrode fingers 11a and 11b are not located in a plan view of the substrate 3, in a region where the plurality of electrode fingers 11a and the plurality of electrode fingers 11b overlap each other when viewed in a direction parallel to the piezoelectric layer 31 and perpendicular to the extending direction of the plurality of electrode fingers 11a and 11b. The film thickness of the dielectric film 41 is smaller than the film thickness of the plurality of electrode fingers 11a and 11b.

According to this configuration, since the dielectric film 41 thinner than the IDT electrode 10 is located in the predetermined region, it is possible to provide the small acoustic wave device 1 (and 1A to 1C) which can adjust the fractional band width without causing deterioration in the Q value.

In addition, the high frequency filters 4, 4A, and 4B according to the present example embodiment include any of the acoustic wave devices 1, 1A, 1B, and 1C.

According to this configuration, the fractional band width of the acoustic wave device of the high frequency filter can be adjusted without causing deterioration in the Q value. Therefore, the high frequency filter having an improved or optimized bandpass characteristic can be provided.

In addition, for example, the high frequency filters 4, 4A, and 4B include the plurality of acoustic wave devices 1, 1A, 1B, or 1C. The dielectric film 41 of the first acoustic wave device in the plurality of acoustic wave devices and the dielectric film 41 of the second acoustic wave device in the plurality of acoustic wave devices have different film thicknesses, materials, or compositions.

According to this configuration, the acoustic wave resonators having different fractional band widths can be combined. Therefore, for example, the high frequency filter having excellent steepness and a wide band can be provided.

In addition, the filter circuit according to the present example embodiment includes the plurality of high frequency filters 4, 4A, or 4B. The plurality of high frequency filters share one substrate 3. The dielectric film 41 of the first high frequency filter in the plurality of high frequency filters and the dielectric film 41 of the second high frequency filter in the plurality of high frequency filters have different film thicknesses, materials, or compositions.

According to this configuration, the plurality of high frequency filters having different pass band widths can be provided on the same substrate. Therefore, the filter circuit including the plurality of high frequency filters can be reduced in size.

### Other Example Embodiments

Hitherto, the acoustic wave devices, the high frequency filters, and the filter circuits according to the present invention have been described by describing example embodiments, examples, and modification examples. The present invention is not limited to the above-described example embodiments, examples, and modification examples. The present invention also includes other example embodiments realized by combining any configuration elements of the above-described example embodiments, examples, and modification examples, or modification examples obtained by applying various modifications to the above-described example embodiments, examples, or modification examples within the scope not departing from the concept of the present invention.

Example embodiments of the present invention can be widely used for communication equipment such as mobile phones, as acoustic wave devices, high frequency filters, and filter circuits in a front end module.

While example embodiments of the present invention have been described above, it is to be understood that variations and modifications will be apparent to those skilled in the art without departing from the scope and spirit of the present invention. The scope of the present invention, therefore, is to be determined solely by the following claims.

What is claimed is:

1. An acoustic wave device comprising:
a substrate;
an interdigital transducer (IDT) electrode on the substrate; and
a first dielectric film on the substrate; wherein
the substrate includes:
a piezoelectric layer on which the IDT electrode is located;
a high acoustic velocity layer having a higher acoustic velocity of a bulk wave propagating through the piezoelectric layer than an acoustic velocity of the acoustic wave propagating through the piezoelectric layer; and
a low acoustic velocity layer between the piezoelectric layer and the high acoustic velocity layer, and having a lower acoustic velocity of the bulk wave than the bulk wave propagating through the piezoelectric layer;
the IDT electrode includes:
a plurality of first electrode fingers and a plurality of second electrode fingers parallel or substantially parallel to each other;
a first busbar electrode to connect one ends of the plurality of first electrode fingers to each other; and
a second busbar electrode to connect one ends of the plurality of second electrode fingers to each other, and facing the first busbar electrode with the plurality of first electrode fingers and the plurality of second electrode fingers interposed therebetween;
on the piezoelectric layer, the first dielectric film is located only in a region where the plurality of first electrode fingers, the plurality of second electrode fingers, the first busbar electrode, and the second busbar electrode are not located, in a region between the first busbar electrode and the second busbar electrode in a plan view of the substrate; and
a film thickness of the first dielectric film is smaller than a film thickness of the plurality of first electrode fingers and the plurality of second electrode fingers.

2. The acoustic wave device according to claim 1, further comprising:
a reflection electrode adjacent to the IDT electrode in a direction perpendicular or substantially perpendicular to an extending direction of the plurality of first electrode fingers and the plurality of second electrode fingers; wherein
the reflection electrode includes:
a plurality of third electrode fingers parallel or substantially parallel to the plurality of first electrode fingers and the plurality of second electrode fingers;
a third busbar electrode that connects one ends of the plurality of third electrode fingers to each other; and
a fourth busbar electrode that connects the other ends of the plurality of third electrode fingers to each other;
on the piezoelectric layer, the first dielectric film is located only in a region where the plurality of first electrode fingers, the plurality of second electrode fingers, the first busbar electrode, and the second busbar electrode are not located, in a region between the first busbar electrode and the second busbar electrode in a plan view of the substrate; and
on the piezoelectric layer, the first dielectric film is located only in a region where the plurality of third electrode fingers, the third busbar electrode, and the fourth busbar electrode are not located, in a region between the third busbar electrode and the fourth busbar electrode in the plan view of the substrate.

3. The acoustic wave device according to claim 1, wherein when an acoustic impedance of the IDT electrode is defined as R_{IDT}, the film thickness of the plurality of first electrode fingers and the plurality of second electrode fingers is defined as t_{IDT}, an acoustic impedance of the first dielectric film located between the plurality of first electrode fingers and the plurality of second electrode fingers is defined as R_{DIE}, and the film thickness of the first dielectric film is defined as t_{DIE}, a relationship of R_{IDT}×t_{IDT}>R_{DIE}×t_{DIE} is satisfied.

4. The acoustic wave device according to claim 1, wherein
the IDT electrode is a multilayer body including n layers where n is a natural number;
the first dielectric film is a multilayer body including m layers where m is a natural number;
when an acoustic impedance of a k-th layer of the IDT electrode is defined as R_{IDTk}, a film thickness of a k-th layer of the IDT electrode is defined as t_{IDTk}, an acoustic impedance of a k-th layer of the first dielectric film between the plurality of first electrode fingers and the plurality of second electrode fingers is defined as R_{DIEk}, and a film thickness of the k-th layer of the first dielectric film is defined as t_{DIEk}, a relationship of
$${\sum }_{k = 1}^{n} {R}_{IDTk} \times {t}_{IDTk} > {\sum }_{k = 1}^{m} {R}_{DIEk} \times {t}_{DIEk}$$
is satisfied.

5. The acoustic wave device according to claim 1, wherein a relative dielectric constant of the first dielectric film is 5 or higher.

6. The acoustic wave device according to claim 1, wherein a relative dielectric constant of the first dielectric film is 10 or higher.

7. The acoustic wave device according to claim 1, wherein the film thickness of the first dielectric film is equal to or smaller than about 50% of the film thickness of the plurality of first electrode fingers and the plurality of second electrode fingers.

8. The acoustic wave device according to claim 1, wherein the film thickness of the first dielectric film is equal to or smaller than about 20% of the film thickness of the plurality of first electrode fingers and the plurality of second electrode fingers.

9. The acoustic wave device according to claim 1, wherein the piezoelectric layer includes either one of lithium tantalate or lithium niobate.

10. The acoustic wave device according to claim 1, wherein the first dielectric film includes any one of silicon nitride, aluminum oxide, yttrium oxide, tantalum oxide, titanium oxide, hafnium oxide, zirconium oxide, aluminum nitride, or sialon.

11. The acoustic wave device according to claim 1, wherein the IDT electrode includes a main electrode layer including aluminum, and a close contact layer between the main electrode layer and the piezoelectric layer.

12. The acoustic wave device according to claim 1, wherein a thermal conductivity of the first dielectric film is higher than a thermal conductivity of the piezoelectric layer.

13. The acoustic wave device according to claim 1, further comprising a second dielectric film on the IDT electrode and the first dielectric film, and including a material or a composition different from a material or a composition of the first dielectric film.

14. The acoustic wave device according to claim 13, wherein a relative dielectric constant of the second dielectric film is lower than a relative dielectric constant of the first dielectric film.

15. The acoustic wave device according to claim 13, wherein a film thickness of the second dielectric film is smaller than the film thickness of the first dielectric film.

16. The acoustic wave device according to claim 13, wherein the second dielectric film includes any one of silicon oxide, silicon nitride, or silicon oxynitride.

17. An acoustic wave device comprising:
a substrate;
an interdigital transducer (IDT) electrode on the substrate; and
a first dielectric film on the substrate; wherein
the substrate includes:
a piezoelectric layer on which the IDT electrode is located;
a high acoustic velocity layer having a higher acoustic velocity of a bulk wave propagating through the piezoelectric layer than an acoustic velocity of the acoustic wave propagating through the piezoelectric layer; and
a low acoustic velocity layer between the piezoelectric layer and the high acoustic velocity layer and having a lower acoustic velocity of the bulk wave than the bulk wave propagating through the piezoelectric layer;
the IDT electrode includes:
a plurality of first electrode fingers and a plurality of second electrode fingers which are parallel or substantially parallel to each other;
a first busbar electrode to connect one ends of the plurality of first electrode fingers to each other; and
a second busbar electrode to connect one ends of the plurality of second electrode fingers to each other, and facing the first busbar electrode with the plurality of first electrode fingers and the plurality of second electrode fingers interposed therebetween;
on the piezoelectric layer, the first dielectric film is located only in a region where the plurality of first electrode fingers and the plurality of second electrode fingers are not located in a plan view of the substrate, in a region where the plurality of first electrode fingers and the plurality of second electrode fingers overlap each other when viewed in a direction parallel or substantially parallel to the piezoelectric layer and perpendicular or substantially perpendicular to an extending direction of the plurality of first electrode fingers and the plurality of second electrode fingers; and
a film thickness of the first dielectric film is smaller than a film thickness of the plurality of first electrode fingers and the plurality of second electrode fingers.

18. A high frequency filter comprising:
the acoustic wave device according to claim 1.

19. The high frequency filter according to claim 18, wherein
a plurality of the acoustic wave devices are provided; and
the first dielectric film of a first acoustic wave device in the plurality of acoustic wave devices and the first dielectric film of a second acoustic wave device in the plurality of acoustic wave devices have different film thicknesses, materials, or compositions.

20. A filter circuit comprising:
a plurality of the high frequency filters according to claim 18; wherein
the plurality of high frequency filters share one of the substrates; and
the first dielectric film of a first high frequency filter in the plurality of high frequency filters and the first dielectric film of a second high frequency filter in the plurality of high frequency filters have different film thicknesses, materials, or compositions.
